(19) United States
(12) Patent Application Publication
(10) Pub. No.: US 2020/0303490 A1
(43) Pub. Date: Sep. 24, 2020

(54) DISPLAY DEVICE

(71) Applicant: Japan Display Inc., Minato-ku (JP)

(72) Inventors: Yasushi TOMIOKA, Tokyo (JP); Hajime Yamaguchi, Tokyo (JP)

(73) Assignee: Japan Display Inc., Minato-ku (JP)

(21) Appl. No.: 16/898,559

(22) Filed: Jun. 11, 2020

Related U.S. Application Data
(63) Continuation of application No. PCT/JP2018/036496, filed on Sep. 28, 2018.

(30) Foreign Application Priority Data
Dec. 15, 2017 (JP) 2017-240552

(51) Int. Cl. H01L 27/32; H01L 51/52

(52) U.S. Cl. CPC H01L 27/3276; H01L 2227/323; H01L 51/5253

(57) ABSTRACT

According to one embodiment, a display device includes a substrate, a first organic film, wiring lines, a second organic film, and a first inorganic film. The substrate has a first area including a display area, a second area including a mounting area, and a third area located between the first area and the second area. The first organic film is disposed on the substrate in the third area. The wiring lines are arranged at intervals in a first direction on the first organic film and extend in a second direction crossing the first direction. The second organic film covers the first organic film and the wiring lines in the third area. The first inorganic film is disposed on the second organic film.

### CROSS-REFERENCE TO RELATED APPLICATIONS

This application is a Continuation Application of PCT Application No. PCT/JP2018/036496, filed Sep. 28, 2018 and based upon and claiming the benefit of priority from Japanese Patent Application No. 2017-240552, filed Dec. 15, 2017, the entire contents of all of which are incorporated herein by reference.

### FIELD

Embodiments described herein relate generally to a display device.

### BACKGROUND

In a display device used for a mobile telephone, a personal digital assistant (PDA) and the like, from the perspective of performance, design and the like, narrowing of a frame is required. As an example of narrowing of a frame, a method of bending a part of a display panel to locate a mounting portion on which other wiring substrates and the like are mounted below a display surface is known. However, in some cases, wiring lines disposed in a bend area may be broken by the impact of a stress caused by bending.

The present embodiment aims to provide a display device which can suppress breaking of wiring lines caused by bending and improve reliability.

### BRIEF DESCRIPTION OF THE DRAWINGS

FIG. 1 is a plan view showing the configuration of a display device 1 according to the present embodiment.

FIG. 2 is an illustration showing a state where a bend area BA shown in FIG. 1 is bent.

FIG. 3 is a cross-sectional view showing a display area DA of the display device 1 shown in FIG. 1.

FIG. 4 is a cross-sectional view taken along line A-A′ shown in FIG. 1.

FIG. 5 is a cross-sectional view taken along line B-B′ shown in FIG. 1.

FIG. 6 is a cross-sectional view showing an example of the manufacturing method of the display device 1 shown in FIG. 5.

FIG. 7 is a cross-sectional view showing a manufacturing process following FIG. 6.

FIG. 8 is a cross-sectional view showing a manufacturing process following FIG. 7.

FIG. 9 is a cross-sectional view showing a manufacturing process following FIG. 8.

FIG. 10 is a cross-sectional view showing a manufacturing process following FIG. 9.

FIG. 11 is a cross-sectional view showing a manufacturing process following FIG. 10.

FIG. 12 is a cross-sectional view showing a manufacturing process following FIG. 11.

FIG. 13 is a plan view showing an example of a first inorganic film IL1 shown in FIG. 4.

FIG. 14 is an illustration showing another example of the first inorganic film IL1.

FIG. 15 is an illustration showing another example of the first inorganic film IL1.

FIG. 16 is an illustration showing another example of the first inorganic film IL1.

FIG. 17 is an illustration showing another example of the first inorganic film IL1.

FIG. 18 is a cross-sectional view showing a bend area BA as a comparative example.

FIG. 19 is a cross-sectional view taken along line B-B′ shown in FIG. 1 according to a modification example of the present embodiment.

FIG. 20 is a cross-sectional view showing another example of the bend area BA.

FIG. 21 is a cross-sectional view showing another example of the bend area BA.

FIG. 22 is a cross-sectional view showing another example of the bend area BA.

FIG. 23 is a cross-sectional view showing another example of the bend area BA.

FIG. 24 is a cross-sectional view showing another example of the bend area BA.

### DETAILED DESCRIPTION

In general, according to one embodiment, there is provided a display device including a substrate, a first organic film, wiring lines, a second organic film and a first inorganic film. The substrate has a first area including a display area, a second area including a mounting area and a third area located between the first area and the second area. The first organic film is disposed on the substrate in the third area. The wiring lines are arranged at intervals in a first direction on the first organic film and extend in a second direction crossing the first direction. The second organic film covers the first organic film and the wiring lines in the third area. The first inorganic film is disposed on the second organic film.

According to another embodiment, there is provided a display device including a substrate, a first organic film, wiring lines, a second organic film and a first inorganic film. The substrate has a first area including a display area, a second area including a mounting area and a third area located between the first area and the second area, and is bent in the third area such that the first area and the second area are opposed to each other. The first organic film is formed on the substrate in the third area. The wiring lines are arranged at intervals in a first direction on the first organic film. The second organic film covers the wiring lines and the first organic film. The first inorganic film is formed on the second organic film.

The present embodiment will be described hereinafter with reference to the accompanying drawings. The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, and the like of the respective parts are illustrated schematically in the drawings, rather than as an accurate representation of what is implemented, but such schematic illustration is merely exemplary, and in no way restricts the interpretation of the invention. In addition, in the specification and drawings, composition elements which function in the same or a similar manner to those described in connection with preceding drawings are denoted by the same reference numbers, and detailed explanations of them that are considered redundant may be arbitrarily omitted.

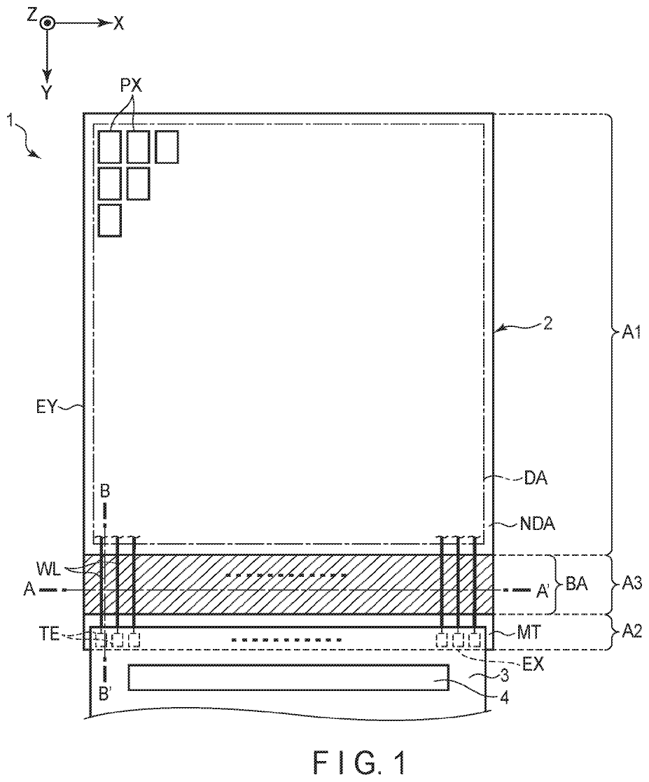

FIG. 1 is a plan view showing the configuration of a display device 1 according to the present embodiment. In the present embodiment, the display device 1 is, for example, an organic electroluminescent (EL) display device including an organic EL element. However, the display device 1 may be another display device such as a liquid crystal display device including a liquid crystal layer or an electronic paper type display device including an electrophoretic element or the like.

FIG. 1 shows a three-dimensional space defined by a first direction X, a second direction Y perpendicular to the first direction X, and a third direction Z perpendicular to the first direction X and the second direction Y. Note that the first direction X and the second direction Y may cross each other at an angle other than 90 degrees. In addition, in the present embodiment, the third direction Z is defined as an upward direction and a direction opposite to the third direction Z is defined as a downward direction. When described as “the second member above the first member” and “the second member below the first member”, the second member may be in contact with the first member or may be separated from the first member. In the latter case, the third member may be interposed between the first member and the second member.

The display device 1 includes a display panel 2, a wiring substrate 3 and the like.

The display panel 2 has, for example, a quadrangular shape and has a rectangular shape in the illustrated example. In the illustrated example, short sides EX of the display panel 2 are parallel to the first direction X, and long sides EY of the display panel 2 are parallel to the second direction Y. The third direction Z corresponds to a thickness direction of the display panel 2. A main surface of the display panel 2 is parallel to an X-Y plane defined by the first direction X and the second direction Y. Note that the display panel 2 may have a shape other than a rectangular shape and may have, for example, curved corners.

The display panel 2 has a display area DA, a non-display area NDA and a mounting area MT. The display area DA is an area which displays images and includes, for example, a plurality of pixels PX arranged in a matrix. The pixel PX includes an organic EL element which will be described later, a switching element which drives the organic EL element, and the like. The non-display area NDA is located outside the display area DA and surrounds the display area DA. The mounting area MT is disposed along the short side EX of the display panel 2. The mounting area MT includes a plurality of terminals TE which electrically connect the display panel 2 to an external device or the like.

The display panel 2 includes a plurality of wiring lines WL electrically connected to the pixels PX. The wiring lines WL are drawn from the display area DA toward the mounting area MT and are connected to the terminals TE. In the illustrated example, the wiring lines WL extend along the second direction Y and are arranged along the first direction X. A power supply potential and a signal potential supplied from the external device are supplied to the pixels PX via the terminals TE and the wiring lines WL.

The wiring substrate 3 is mounted on the mounting area MT and is electrically connected to the display panel 2. The wiring substrate 3 is, for example, a flexible printed circuit board. The wiring substrate 3 includes a driver IC chip 4 which drives the display panel 2 and the like. The driver IC chip 4 is electrically connected to the pixels PX via the terminals TE and the wiring lines WL. Note that the driver IC chip 4 may be mounted on the display panel 2. The length of the edges parallel to the first direction X of the wiring substrate 3 is less than the length of the short sides EX in the illustrated example but may be substantially equal to the length of the short sides EX.

In the present embodiment, the display panel 2 has flexibility. That is, the display panel 2 has a bend area BA in the non-display area NDA as indicated by diagonal lines in the drawing. The bend area BA is an area in which the display panel 2 is bent when the display device 1 is accommodated in a housing of an electronic device or the like. The above-described wiring lines WL pass through the bend area BA and connect the pixels PX and the terminals TE.

In the present embodiment, an area including the display area DA will be referred to as a first area A1, an area including the mounting area MT will be referred to as a second area A2, and an area including the bend area BA will be referred to as a third area A3.

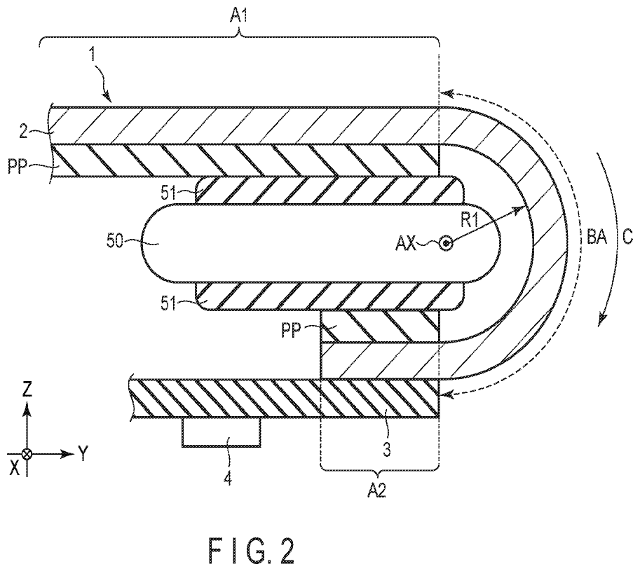

FIG. 2 is an illustration showing a state where the bend area BA shown in FIG. 1 is bent. FIG. 2 shows a plane parallel to a Y-Z plane. Here, only those configurations which are necessary for explanation are illustrated.

The display device 1 includes a support substrate PP and a support member 50 in addition to the display panel 2 and the wiring substrate 3.

The support substrate PP is disposed on a surface opposite to a display surface of the display panel 2. However, the support substrate PP is not disposed in the bend area BA. The support substrate PP functions as a support layer which suppresses curving of the display panel 2 in the display area DA, for example. In addition, the support substrate PP has moisture insulating properties of suppressing intrusion of moisture into the display panel 2 and gas insulating properties of suppressing intrusion of gas into the display panel 2, and functions as a barrier layer. The support substrate PP is, for example, a film made of polyethylene terephthalate. Note that another thin film may be interposed between the support substrate PP and the display panel 2.

The display panel 2 is bent such that the support member 50 is sandwiched in between and is bonded to the support member 50 by an adhesive 51. In the illustrated example, the support member PP and the adhesive 51 are in contact with each other. In a state where the bend area BA is bent, the wiring substrate 3 is located below the display panel 2, and is opposed to the display panel 2 and the support member 50 substantially parallel to the display panel 2 and the support member 50. Note that the support member 50 may be omitted.

In the present embodiment, the bend area BA is bent about a bend axis AX along the first direction X. The bend area BA has the shape of a curved surface. In the illustrated example, the bend area BA is curved along the circumference of a circle. The generatrix of the curved surface formed by the bend area BA is parallel to the bend axis AX. That is, the generatrix of the bend area BA is parallel to the first direction X. Here, a direction from a first area A1 side to a second area A2 side along the curved surface of the bend area BA is defined as a circumferential direction C. In addition, a radius of curvature R1 of the bend area BA is defined as, for example, a distance from the bend axis AX to an inner surface of the display panel 2. The radius of curvature R1 is, for example, 0.3 mm.

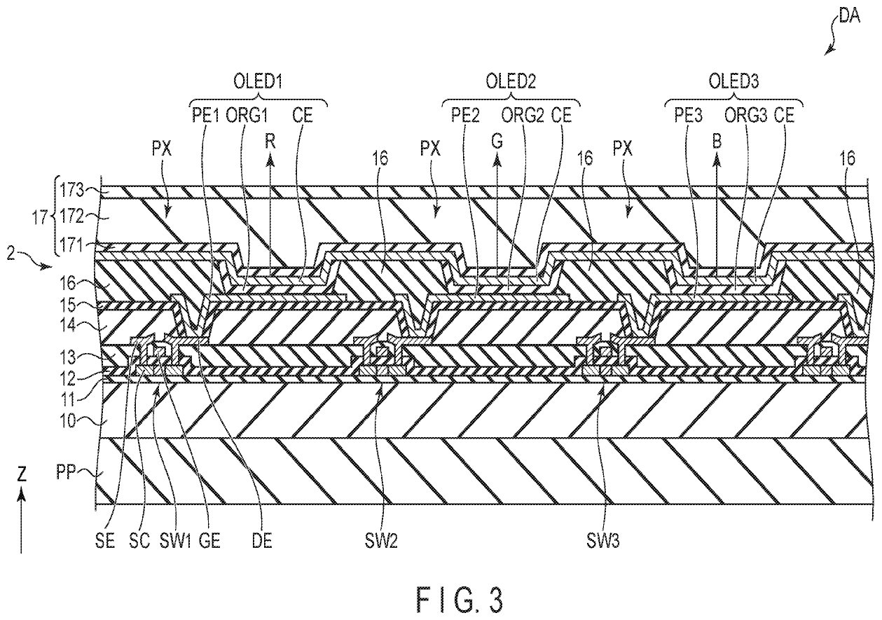

FIG. 3 is a cross-sectional view showing the display area DA of the display device 1 shown in FIG. 1. The display panel 2 includes an insulating substrate 10, insulating films 11 to 16, switching elements SW (SW1, SW2 and SW3), organic EL elements OLED (OLED1, OLED2 and OLED3), a sealing film 17 and the like. In the illustrated example, the support substrate PP is bonded below the insulating substrate 10.

The insulating substrate 10 is made of, for example, an organic insulating material such as polyimide. The insulating film 11 is formed on the insulating substrate 10. The insulating film 11 may include a barrier layer which suppresses intrusion of moisture and the like from the insulating substrate 10 into the organic EL elements OLED. Note that the insulating film 11 may be omitted. In addition, as will be described later, the insulating substrate 10 may have a laminated structure in which an inorganic insulating material is sandwiched between organic insulating materials.

The switching elements SW are formed on the insulating film 11. The switching elements SW are formed of, for example, a thin-film transistor (TFT). The switching elements SW correspond to a top-gate type in the illustrated example but may correspond to a bottom-gate type. The configurations of them will be described below by taking the switching element SW1 as an example.

The switching element SW1 includes a semiconductor layer SC, a gate electrode GE, a source electrode SE and a drain electrode DE.

The semiconductor layer SC is formed on the insulating film 11 and is covered with the insulating film 12. The gate electrode GE is formed on the insulating film 12 and is covered with the insulating film 13. The source electrode SE and the drain electrode DE are formed on the insulating film 13. The source electrode SE and the drain electrode DE are in contact with the semiconductor layer SC respectively in contact holes penetrating the insulating film 13 to the semiconductor layer SC.

The gate electrode GE is made of a metal material such as aluminum (Al), titanium (Ti), silver (Ag), molybdenum (Mo), tungsten (W), copper (Cu) or chromium (Cr) or an alloy made by combining these metal materials, and may have a single-layer structure or a multilayer structure. The above-described metal materials can be applied to the materials of the source electrode SE and the drain electrode DE.

The switching elements SW are covered with the insulating film 14. The insulating film 14 is covered with the insulating film 15. The insulating films 11 to 13 and the insulating film 15 are made of an inorganic insulating material such as silicon oxide, silicon nitride or silicon oxynitride. The insulating film 14 is made of, for example, an organic insulating material such as polyimide.

The organic EL elements OLED are formed on the insulating film 15. In the illustrated example, the organic EL elements OLED correspond to a so-called top-emission type which emits light to a side opposite to the insulating substrate 10. However, the organic EL elements OLED are not limited to this example but may correspond to a so-called bottom-emission type which emits light to the insulating substrate 10 side. For example, the organic EL element OLED1 includes an organic light-emitting layer ORG1 which emits red light, the organic EL element OLED2 includes an organic light-emitting layer ORG2 which emits blue light, and the organic EL element OLED3 includes an organic light-emitting layer ORG3 which emits green light. The configurations of them will be described below by taking the organic EL element OLED1 as an example.

The organic EL element OLED1 is formed of a pixel electrode PE1, a common electrode CE and the organic light-emitting layer ORG1.

The pixel electrode PE1 is disposed on the insulating film 15. The pixel electrode PE1 is in contact with the drain electrode DE of the switching element SW1 in a contact hole formed in the insulating film 15 and the insulating film 14. Accordingly, the pixel electrode PE 1 and the switching element SW1 are electrically connected to each other. The organic light-emitting layer ORG1 is formed on the pixel electrode PE1. The organic light-emitting layer ORG1 may further include an electron injection layer, a hole injection layer, an electron transport layer, a hole transport layer and the like to improve light emission efficiency. The common electrode CE is formed on the organic light-emitting layer ORG1. The common electrode CE and the pixel electrode PE1 are made of, for example, a transparent conductive material such as indium tin oxide (ITO) or indium zinc oxide (IZO).

The organic EL element OLED1 configured as described above emits light at a luminance according to a voltage (or a current) applied between the pixel electrode PE1 and the common electrode CE. Although an illustration is omitted, in the case of a top-emission type, the organic EL element OLED1 preferably includes a reflective layer between the insulating film 15 and the pixel electrode PE1. The reflective layer is made of, for example, a metal material having a high reflectance such as aluminum or silver. A reflective surface, that is, a surface on an organic light-emitting layer ORG1 side of the reflective layer may be flat or may have projections and recesses to have light-scattering properties.

Each organic EL element OLED is delimited for each pixel PX by the insulating films (ribs) 16 made of an organic insulating material. The insulating films 16 are formed on the pixel electrodes PE. In the illustrated example, the insulating films 16 are also in contact with the insulating film 15. The insulating films 16 are made of, for example, polyimide.

The organic light-emitting layers ORG1, ORG2 and ORG3 are in contact with the pixel electrodes PE1, PE2 and PE3 respectively in areas in which the insulating films 16 are not disposed, that is, in areas between the insulating film 16 and the insulating film 16. In the illustrated example, the common electrode CE is formed in the entire display area DA. That is, the common electrode CE is in contact with the organic light-emitting layers ORG1, ORG2 and ORG3 and covers the insulating films 16.

Note that the display panel 2 may include a common organic light-emitting layer over the pixels PX instead. In this configuration, the display panel 2 includes color filters at positions opposed to the organic EL elements OLED. The color filters are made of, for example, a resin material colored red, green, blue or the like.

The sealing film 17 covers the organic EL elements OLED. The sealing film 17 suppresses intrusion of moisture and oxygen into the organic EL elements OLED and suppresses degradation of the organic EL elements. The sealing film 17 includes an inorganic film 171, an organic film 172 and an inorganic film 173.

The inorganic film 171 is formed on the organic EL elements OLED. In the illustrated example, the inorganic film 171 is in contact with the common electrode CE. The inorganic film 173 is located above the inorganic film 171. The organic film 172 is located between the inorganic film 171 and the inorganic film 173 and is in contact with the inorganic film 171 and the inorganic film 173.

The inorganic film 171 and the inorganic film 173 have the function of stopping intrusion of moisture into an organic EL element OLED side. The inorganic film 171 and the inorganic film 173 are transparent and are made of, for example, silicon nitride. The organic film 172 is made of a transparent organic material. Note that, when described as being transparent, it allows to be colored within a range where transmitted light does not affect display.

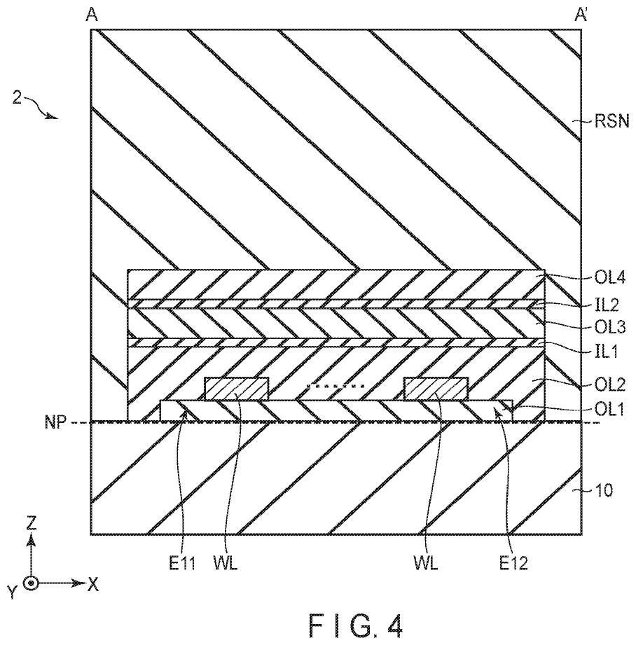

FIG. 4 is a cross-sectional view taken along line A-A′ shown in FIG. 1. FIG. 4 shows a plane parallel to an X-Z plane defined by the first direction X and the third direction Z. In the bend area BA, the display panel 2 includes the insulating substrate 10, the wiring lines WL, a first organic film OL1, a second organic film OL2, a third organic film OL3, a fourth organic film OL4, a first inorganic film IL1, a second inorganic film IL2 and a resin layer RSN.

The first organic film OL1 is located on the insulating substrate 10. The wiring lines WL are located on the first organic film OL1 and are covered with the second organic film OL2. In the first direction X, a first end E11 and a second end E11 of the first organic film OL1 are covered with the second organic film OL2. In other words, the second organic film OL2 is in contact with the wiring lines WL and the first organic film OL1, and is also in contact with the insulating substrate 10 such that the first organic film OL1 is sandwiched in between.

The first inorganic film IL1 is located on the second organic film OL2. In the illustrated example, the first inorganic film IL1 covers an entire upper surface of the second organic film OL2. The third organic film OL3 is located on the first inorganic film IL1. In the illustrated example, the third organic film OL3 covers an entire upper surface of the first inorganic film IL1. The second inorganic film IL2 is located on the third organic film OL3. In the illustrated example, the second inorganic film IL2 covers an entire upper surface of the third organic film OL3. The fourth organic film OL4 is located on the second inorganic film IL2. In the illustrated example, the fourth organic film OL4 covers an entire upper surface of the second inorganic film IL2.

The resin layer RSN is located on the fourth organic film OL4. The resin layer RSN covers the second inorganic film IL2, the third organic film OL3, the first inorganic film IL1 and the second organic film OL2 and is also in contact with the insulating substrate 10.

The first organic film OL1, the second organic film OL2 and the third organic film OL3 are made of, for example, an organic insulating material such as polyimide. To improve adhesion, the first organic film OL1 and the second organic film OL2 are preferably made of the same material. In addition, when the first organic film OL1, the second organic film OL2 and the third organic film OL3 are made of polyimide, at least the first organic film OL1 and the second organic film OL2 contain fluorine. The third organic film OL3 may contain fluorine or may not contain fluorine. The fourth organic film OL4 is, for example, a resist film. The resin layer RSN is, for example, acrylic resin and is cured by ultraviolet irradiation. This resin layer RSN functions as a protective layer which protects the wiring lines WL. In addition, the first inorganic film IL1 and the second inorganic film IL2 are made of an inorganic insulating material such as silicon oxide or silicon nitride.

The Young's moduli of the first organic film OL1, the second organic film OL2, the third organic film OL3 and the fourth organic film OL4 are greater than the Young's modulus of the resin layer RSN. Furthermore, the Young's moduli of the first inorganic film IL1 and the second inorganic film IL2 are greater than the Young's moduli of the first to fourth organic films OL1 to OL4.

In the above-described configuration, a neutral plane NP in a state where the bend area BA is bent is located in the vicinity of the boundary between the insulating substrate 10 and the first organic film OL1 as indicated by a dashed line. Here, the neutral plane NP is a plane in which a tensile stress and a compressive stress generated when the bend area BA is bent are balanced.

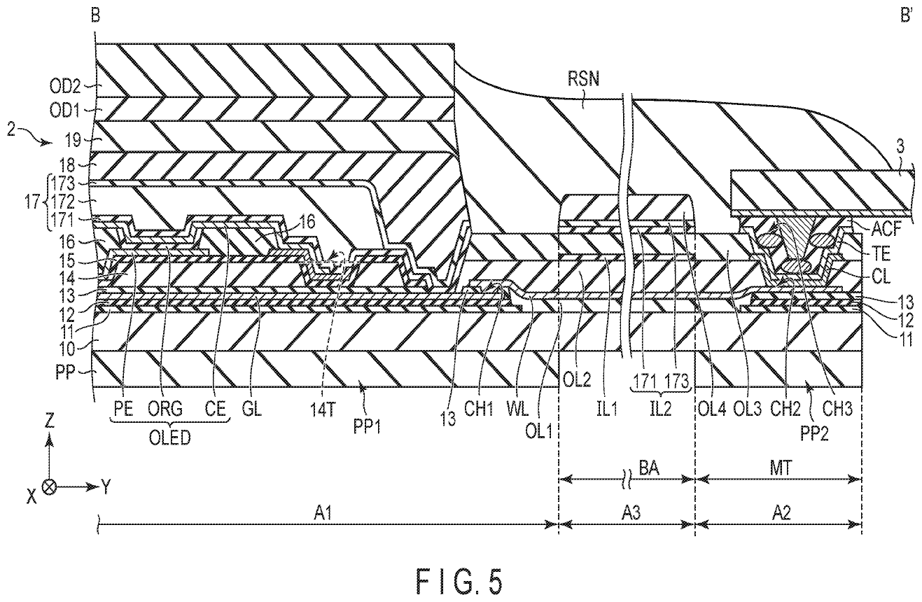

FIG. 5 is a cross-sectional view taken along line B-B′ shown in FIG. 1. FIG. 5 shows a plane parallel to a Y-Z plane defined by the second direction Y and the third direction Z. The first area A1, the third area A3 and the second area A2 are arranged in this order along the second direction Y.

The display panel 2 further includes a wiring line GL, a resist film 18, an adhesive layer 19, optical elements OD1 and OD2, a conductive layer CL and the terminal TE in addition to the insulating substrate 10, the wiring line WL, the insulating films 11 to 16, the organic EL element OLED, the sealing film 17, the first to fourth organic films OL1 to OL4, the first inorganic film IL1, the second inorganic film IL2 and the resin layer RSN.

The first area A1 corresponds to an area in which a support substrate PP1 is bonded to the insulating substrate 10. The support substrate PP1 is the support substrate PP overlapping the organic EL element OLED. The mounting area MT corresponds to an area in which a support substrate PP2 is bonded to the insulating substrate 10. The support substrate PP2 is the support substrate PP overlapping the terminal TE. The bend area BA corresponds to an area in which the support substrate PP is not disposed, that is, an area between the support substrate PP1 and the support substrate PP2. Note that the support substrate PP1 corresponds to the first support substrate and the support substrate PP2 corresponds to the second support substrate.

The insulating substrate 10 is located over the first area A1, the second area A2 and the third area A3. The insulating films 11 to 13 are formed in the substantially entire first area A1 and the substantially entire second area A2 but are not disposed in the third area A3. In the illustrated example, the insulating films 11 to 13 are removed in an area which is slightly wider than the third area A3.

The wiring line GL is located on the insulating film 12 and is covered with the insulating film 13 in the first area A1. This wiring line GL can be formed simultaneously with the gate electrode GE of the switching element SW shown in FIG. 3.

The insulating film 14 is formed in the first area A1. The insulating film 14 has a groove 14T which exposes the insulating film 13. Accordingly, intrusion of moisture from a mounting area MT side to a display area DA side via the insulating film 14 is suppressed, and degradation of the organic EL element OLED is suppressed. This groove 14T is preferably formed in the shape of a ring surrounding the display area DA. In the first area A1, the wiring line GL and the insulating films 11 to 13 extend more toward the mounting area MT than the insulating film 14.

The insulating film 15 is located on the insulating film 14. The insulating film 15 is in contact with the insulating film 13 in the groove 14T. In addition, the insulating film 15 extends more toward the mounting area MT than the insulating film 14 and is also in contact with the insulating film 13. The insulating film 16 is located in a more inward area than the groove 14T, that is, located farther from the mounting area MT (or closer to the display area DA) than the groove 14T. The organic EL element OLED is located on the insulating film 15 and between the insulating film 16 and the insulating film 16.

The first organic film OL1 is located in the entire third area A3 and is also located in the first area A1 and the second area A2. The first organic film OL1 is in contact with the insulating substrate 10 in the third area A3. In addition, the first organic film OL1 is in contact with the insulating substrate 10 and covers at least parts of the insulating films 11 to 13 in the first area A1 and the second area A2. In the first area A1 and the second area A2, since the insulating films 11 to 13 are covered with the first organic film OL1, a difference in level caused by the insulating films 11 to 13 is moderated.

The wiring line WL extends from an end of the first area A1 to the second area A2. The wiring line WL is formed on the first organic film OL1 in the third area A3. In addition, the wiring line WL is formed on the insulating film 13 in the first area A1 and the second area A2. The wiring line WL is in contact with the wiring line GL in a contact hole CH1 formed in the insulating film 13 in the first area A1. The wiring line WL can be formed simultaneously with the source electrode SE and the drain electrode DE of the switching element SW shown in FIG. 3.

The second organic film OL2 covers the entire wiring line WL. The second organic film OL2 is located in the entire third area A3, and is also partly located in the first area A1 and the second area A2. In the illustrated example, the second organic film OL2 is in contact with the wiring line WL and the insulating film 13 and is also in contact with the wiring line GL in the first area A1. The second organic film OL2 is in contact with the wiring line WL and is also in contact with the insulating film 13 in the second area A2. The second organic film OL2 can be formed simultaneously with the insulating film 14.

The second organic film OL2 has a contact hole CH2 which exposes the wiring line WL in the second area A2. The conductive layer CL is disposed in this contact hole CH2 and is in contact with the wiring line WL. The conductive layer CL can be formed simultaneously with the pixel electrode PE of the organic EL element OLED.

The first inorganic film IL1 is located on the second organic film OL2 in the third area A3. In the illustrated example, the first inorganic film IL1 covers the range of the third area A3 but does not cover both ends of the first organic film OL1 and the second organic film OL2. That is, the first inorganic film IL1 does not overlap the insulating films 11 to 13 located in the first area A1 and the second area A2 in the third direction Z. The first inorganic film IL1 can be formed simultaneously with the insulating film 15.

The third organic film OL3 covers the entire first inorganic film IL1. The third organic film OL3 is located in the entire third area A3 and is also partly located in the first area A1 and the second area A2.

The third organic film OL3 is in contact with the second organic film OL2 in the first area A1 and the second area A2. The third organic film OL3 can be formed simultaneously with the insulating film 16. That is, the first inorganic film IL1 is not formed at a third area A3 side end of the first area A1 which is particularly likely to be subjected to a stress when the display panel 2 is bent. The adhesion between the second organic film OL2 and the first inorganic film IL1 and the adhesion between the third organic film OL3 and the first inorganic film IL1 are lower than the adhesion between the second organic film OL2 and the third organic film OL3. Therefore, when the display panel 2 is bent, the first inorganic film IL1 in the third area A3 is likely to peel off. If the first inorganic film IL1 is formed at the third area A3 side end of the first area A1, the second organic film OL2 and the third organic film OL3 will not be in contact with each other in an area which is likely to be subjected to a stress. Therefore, the first inorganic film IL1 peels off in this area, and the peeling of the first inorganic film IL1 causes the organic film 171, etc., to peel off and further causes members in the display area DA to peel off.

In the present embodiment, the first inorganic film IL1 is smaller than the second organic film OL2 and the third organic film OL3. Therefore, the first area A1 includes a portion in which the second organic film OL2 and the third organic film OL3 are in contact with each other on its third area A3 side. When the display panel 2 is bent and if the first inorganic film IL1 in the third area A3 peels off, the second organic film OL2 and the third organic film OL3 are firmly bonded to each other, and propagation of the impact of the peeling can be suppressed.

The third organic film OL3 has a contact hole CH3 which exposes the conductive layer CL in the second area A2. The terminal TE is disposed in this contact hole CH3 and is in contact with the conductive layer CL. Accordingly, the terminal TE and the wiring line WL are electrically connected to each other via the conductive layer CL. The terminal TE can be formed simultaneously with the common electrode CE of the organic EL element OLED.

The sealing film 17 covers the organic EL element OLED in the first area A1 and also partly covers end surfaces of the second organic film OL2 and the third organic film OL3. More specifically, the inorganic film 171 extends more toward the mounting area MT than the insulating film 14 and is in contact with the end surface of the second organic film OL2 and the end surface of the third organic film OL3. In the illustrated example, the inorganic film 171 is in contact with the insulating film 15, the insulating film 13 and the wiring line GL between the insulating film 14 and the second organic film OL2. The organic film 172 is located within an area in which the insulating film 14 is disposed. The inorganic film 173 extends more toward the mounting area MT than the organic film 172 and is in contact with the inorganic film 171.

On the third organic film OL3 in the third area A3, the second inorganic film IL2 is disposed in an area substantially overlapping the first inorganic film IL1. That is, the second inorganic film IL2 covers the range of the third area A3 but does not cover both ends of the third organic film OL3. In addition, the second inorganic film IL2 does not overlap the insulating films 11 to 13 located in the first area A1 and the second area A2 in the third direction Z. The second inorganic film IL2 is formed of, for example, the inorganic film 171 and the inorganic film 173 which constitute the sealing film 17. Note that the second inorganic film IL2 may be formed of one of the inorganic films 171 and 173 or may be formed of another inorganic film.

The resist film 18 is formed on the sealing film 17. In the illustrated example, the position of an end of the resist film 18 in the first area A1 is substantially aligned with the position of an end of the inorganic film 171 and an end of the inorganic film 173.

The fourth organic film OL4 is located directly above the second inorganic film IL2 of the third area A3. In other words, the second inorganic film IL2 is formed in an area in which the fourth organic film OL4 is disposed. The fourth organic film OL4 can be formed simultaneously with the resist film 18.

The optical elements OD1 and OD2 are bonded to the resist film 18 by the adhesive layer 19. The optical element OD1 is, for example, an optical member such as a retarder, and the optical element OD2 is, for example, an optical member such as a polarizer.

The display panel 2 configured as described above is bonded to the wiring substrate 3 via an anisotropically conductive film ACF in the second area A2. The anisotropically conductive film ACF contains conductive particles CP in an adhesive. In a state where the anisotropically conductive film ACF is interposed between the terminal TE and the wiring substrate 3, the display panel 2 and the wiring substrate 3 are pressurized to be brought close to each other and are heated. As a result, these two are electrically and physically connected to each other. The resin layer RSN is disposed at least in the third area A3 and covers the fourth organic film OL4. In the illustrated example, the resin layer RSN is disposed from ends of the optical elements OD1 and OD2 to an end of the wiring substrate 3, is in contact with the adhesive layer 19, the resist film 18, the inorganic films 171 to 173, the third organic film OL3, the second inorganic film IL2 and the fourth organic film OL4, and covers the end of the wiring substrate 3.

That is, the second inorganic film IL2 is not formed at the third area A3 side end of the first area A1 which is particularly likely to be subjected to a stress when the display panel 2 is bent. The adhesion between the third organic film OL3 and the second inorganic film IL2 and the adhesion between the fourth organic film OL4 and the second inorganic film IL2 are lower than the adhesion between the third organic film OL3 and the resin layer RSN. Therefore, when the display panel 2 is bent, the second inorganic film IL2 in the third area A3 is likely to peel off. If the second inorganic film IL2 is formed of the inorganic film 171 and the inorganic film 173 which constitute the sealing film 17 continuously from the first area A1 to the third area A3, the peeling of the second inorganic film IL2 in the third area A3 causes the inorganic film 171 and the inorganic film 173 to peel off and further causes members in the display area DA to peel off. In addition, when the display panel 2 is bent and if a crack is generated in the second inorganic film IL2, the crack also propagates and the crack further propagates in the display area DA.

In the present embodiment, the second inorganic film IL2 is formed of the inorganic film 171 and the inorganic film 173 which constitute the sealing film 17 but is not formed continuously from the first area A1 to the third area A3. Therefore, when the display panel 2 is bent and if the second inorganic film IL2 peels off or cracks, peeling of other members and propagation of the crack can be suppressed.

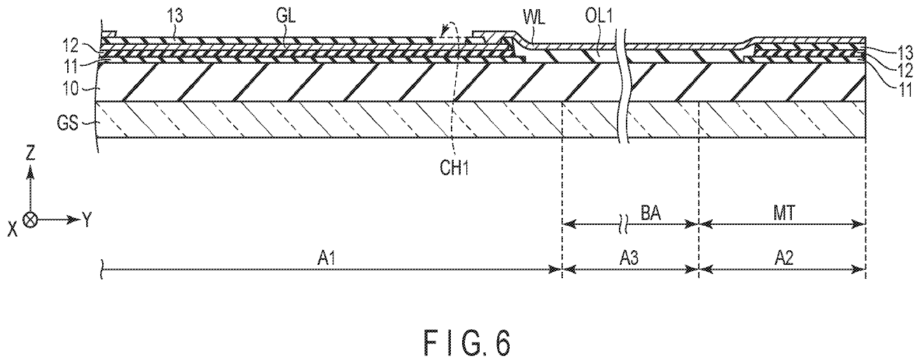

Next, an example of the manufacturing method of the display device 1 shown in FIG. 5 will be described with reference to FIGS. 6 to 12.

As shown in FIG. 6, the insulating substrate 10 made of, for example, an organic insulating material such as polyimide is formed on a glass substrate GS. Then, the insulating film 11 made of, for example, silicon oxide or silicon nitride is formed by, for example, plasma-enhanced chemical vapor deposition (plasma CVD) on the entire insulating substrate 10. After that, the insulating film 11 is removed by, for example, etching in the third area A3.

Then, the insulating film 12 made of, for example, silicon oxide or silicon nitride is formed by, for example, plasma CVD on the insulating film 11 and the insulating substrate 10. Then, the wiring line GL is formed by, for example, sputtering on the insulating film 12. The wiring line GL is formed within the first area A1. The wiring line GL can be made of the same material as and formed simultaneously with the gate electrode GE of the switching element SW shown in FIG. 3. Then, the insulating film 13 made of, for example, silicon oxide or silicon nitride is formed by, for example, plasma CVD on the wiring line GL and the insulating film 12.

Then, the insulating film 12 and the insulating film 13 are removed by etching in the third area A3. At this time, the contact hole CH1 which exposes an end of the wiring line GL is also formed simultaneously. The removing of the insulating film 12 and the insulating film 13 can be performed simultaneously with the forming of the contact holes which connect the source electrode SE and the drain electrode DE of the switching element SW respectively to the semiconductor layer SC shown in FIG. 3.

After that, the first organic film OL1 made of polyimide containing fluorine is formed in the third area A3. Then, the wiring line WL which extends from the end of the wiring line GL to the second area A2 is formed by, for example, sputtering. The wiring line WL is formed on the first organic film OL1 in the third area A3. Both ends of the wiring line WL are formed on the insulating film 13. In the first area A1, the wiring line WL is in contact with the wiring line GL in the contact hole CH1.

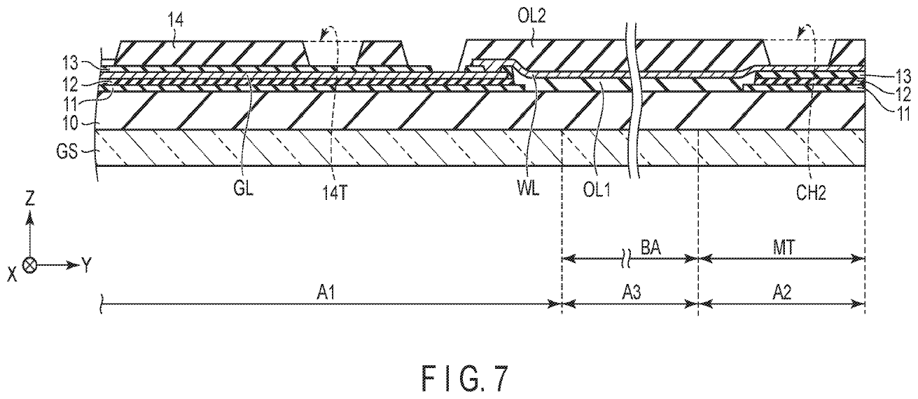

Next, as shown in FIG. 7, the insulating film 14 made of, for example, polyimide containing fluorine is formed on the entire insulating substrate 10. After that, the insulating film 14 is partly removed by lithography. That is, the groove 14T which exposes the insulating film 13 is formed in the insulating film 14 in the first area A1. Since the groove 14T is formed, intrusion of moisture and the like from a second area A2 side to a first area A1 side via the insulating film 14 can be suppressed. Accordingly, degradation of the organic EL element OLED can be suppressed.

On the other hand, the insulating film 14 is not removed in the entire third area A3. That is, the insulating film 14 in the third area A3 corresponds to the second organic film OL2. In the illustrated example, the second organic film OL2 extends to the first area A1 and covers the end of the wiring line WL. In addition, the second organic film OL2 extends to the second area A2. In the second area A2, the contact hole CH2 which exposes the end of the wiring line WL is formed in the second organic film OL2.

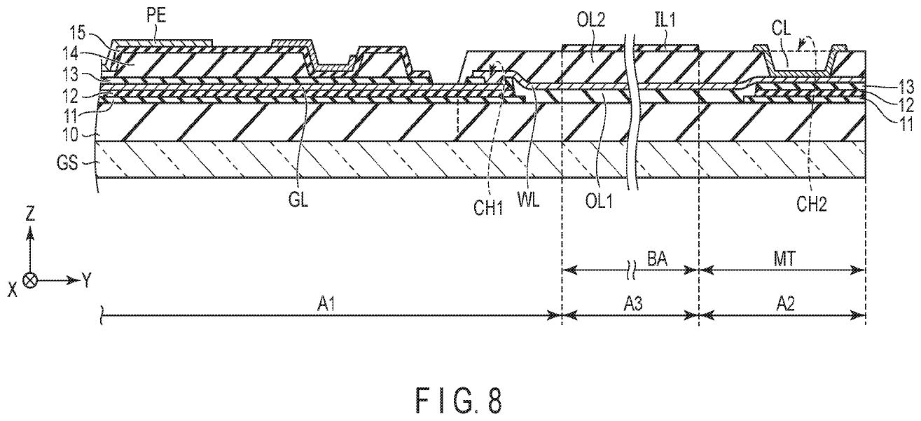

Then, as shown in FIG. 8, the insulating film 15 made of, for example, silicon oxide or silicon nitride is formed by, for example, plasma CVD on the entire insulating substrate 10. After that, the insulating film 15 is partly removed in the first area A1 and the second area A2 by etching. As a result, the second organic film OL2 is partly exposed in the first area A1 and the second area A2. In other words, the insulating film 15 is formed in the third area A3. The insulating film 15 in the third area A3 corresponds to the first inorganic film IL1. The first inorganic film IL1 extends to the vicinity of the first area A1 in the illustrated example but does not overlap the contact hole CH1. In addition, the first inorganic film IL1 extends to the vicinity of the second area A2 but does not cover the contact hole CH2. Note that the insulating film 15 covers the insulating film 14 and is also in contact with the insulating film 13 in the first area A1. The insulating film 15 in the first area A1 does not connect with the first inorganic film IL1. Therefore, when the display panel 2 is bent and even if a crack is generated in the first inorganic film IL1, propagation of the crack to the display area DA can be suppressed.

Then, the pixel electrode PE is formed on the insulating film 15 by, for example, sputtering. At this time, the conductive layer CL is formed in the second area A2. The conductive layer CL is formed in the contact hole CH2 and is in contact with the wiring line WL.

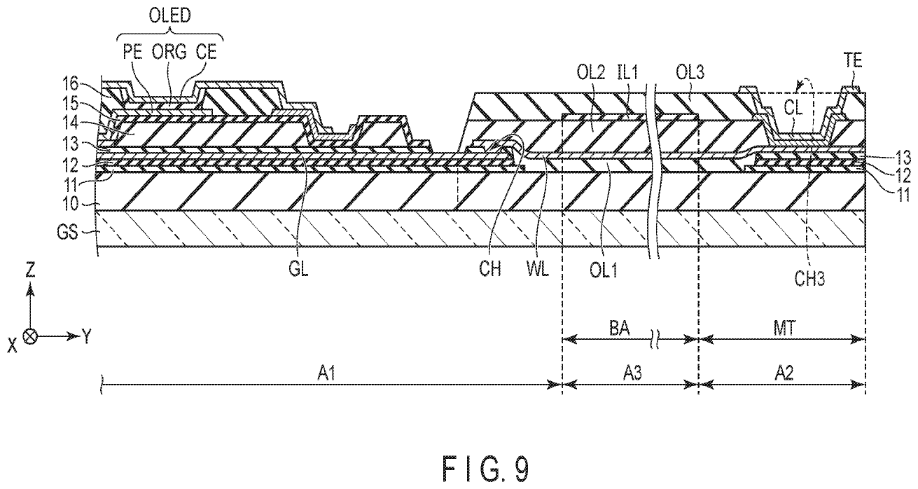

Then, as shown in FIG. 9, the insulating film 16 made of, for example, polyimide is formed on the entire insulating substrate 10. When the insulating film 16 is made of polyimide, the insulating film 16 may contain fluorine or may not contain fluorine. After that, the insulating film 16 is partly removed by lithography. Accordingly, the insulating films 16 as ribs are formed in the first area A1. On the other hand, the insulating film 16 is not removed but forms the third organic film OL3 in the third area A3. That is, the insulating film 16 in the third area A3 corresponds to the third organic film OL3. The third organic film OL3 covers the first inorganic film IL1 and is also in contact with the second organic film OL2. The contact hole CH3 which exposes the conductive layer CL is formed in the second area A2.

After that, the organic light-emitting layer ORG is formed by, for example, mask deposition or printing between the rib and the rib in the first area A1. Then, the common electrode CE is formed by, for example, sputtering. The common electrode CE is in contact with the organic light-emitting layer ORG between the insulating film 16 and the insulating film 16 as the ribs in the first area A1. Accordingly, the organic EL element OLED is formed. In the illustrated example, the common electrode CE also covers the insulating film 16. At this time, the terminal TE is formed in the second area A2. The terminal TE is formed in the contact hole CH3 and is in contact with the conductive layer CL. Accordingly, the wiring line WL and the terminal TE are electrically connected to each other.

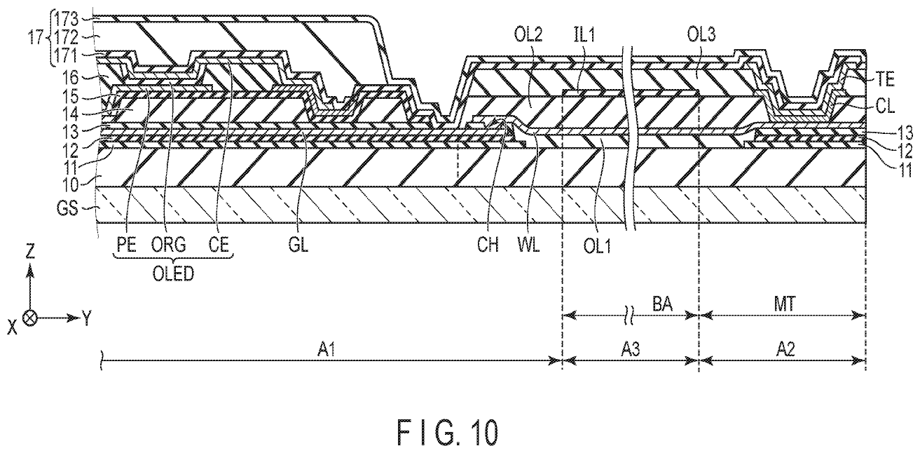

Then, as shown in FIG. 10, the sealing film 17 is formed on the entire insulating substrate 10. More specifically, first, the inorganic film 171 made of, for example, silicon nitride is formed by, for example, plasma CVD. The inorganic film 171 is formed on the entire insulating substrate 10. Then, the organic film 172 made of a transparent organic insulating material is formed on the inorganic film 171. The organic film 172 is formed within the first area A1. In the illustrated example, the organic film 172 overlaps the insulating film 14 but does not overlap the second organic film OL2. Then, the inorganic film 173 made of, for example, silicon nitride is formed by, for example, plasma CVD. The inorganic film 173 is formed on the entire insulating substrate 10. That is, the inorganic film 173 covers the organic film 172 and is also in contact with the inorganic film 171.

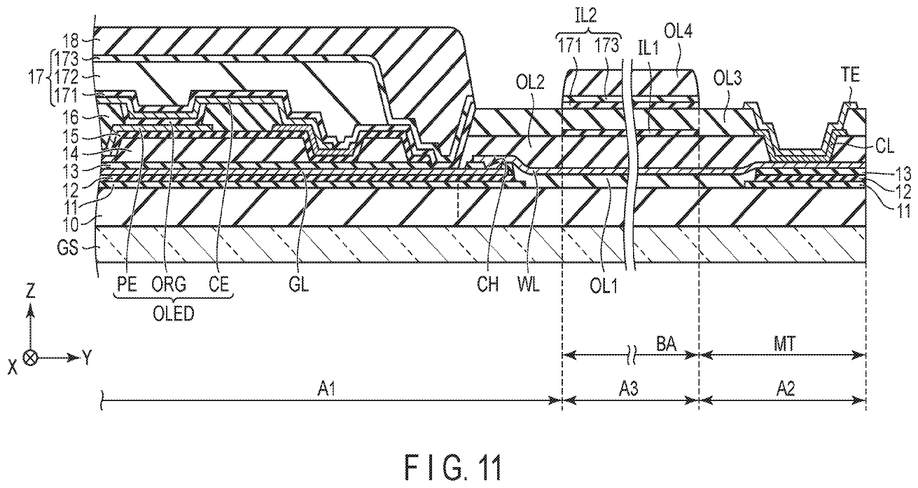

Then, as shown in FIG. 11, the resist film 18 is selectively applied to the inorganic film 173. The resist film 18 is disposed in an entire area located closer to the organic EL element OLED than the wiring line WL. In addition, the resist film 18 is disposed in the entire third area A3 and forms the fourth organic film OL4. That is, the resist film 18 in the third area A3 corresponds to the fourth organic film OL4. In the illustrated example, the fourth organic film OL4 is located in an area substantially overlapping the first inorganic film IL1.

Then, etching is performed using this resist film 18 as a mask. Accordingly, the second inorganic film IL2 covered with the fourth organic film OL4 is formed in the third area A3. That is, the inorganic films 171 and 173 in the third area A3 correspond to the second inorganic film IL2. That is, the second inorganic film IL2 does not connect with the inorganic films 171 and 173. Therefore, when the display panel 2 is bent and even if a crack is generated in the second inorganic film IL2, propagation of the crack to the display area DA can be suppressed. Note that the second inorganic film IL2 includes both of the inorganic films 171 and 173 in the illustrated example but may be formed of one of the inorganic films 171 and 173.

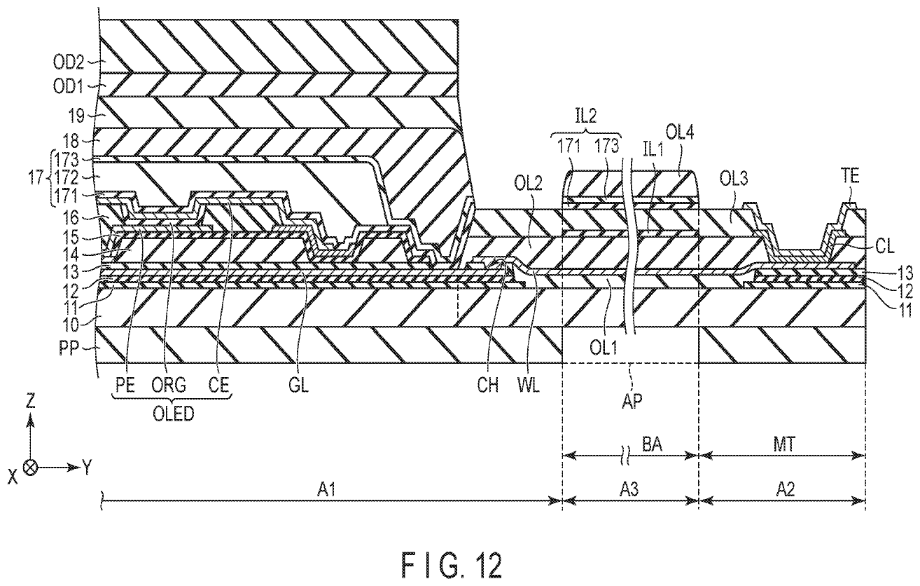

Then, as shown in FIG. 12, the glass substrate GS is peeled off, and then, the support substrate PP is bonded to a lower surface of the insulating substrate 10. For example, the support substrate PP has an aperture AP in an area corresponding to the third area A3. Note that the support substrate PP may be bonded on the entire lower surface of the insulating substrate 10, and then, the support substrate PP in the area corresponding to the third area A3 may be removed by, for example, laser irradiation.

Then, the optical elements OD1 and OD2 are bonded to the resist film 18 via the adhesive layer 19 in the first area A1. The optical element OD1 is, for example, a retarder, and the optical element OD2 is, for example, a polarizer. After that, as shown in FIG. 5, the terminal TE is bonded to the wiring substrate 3 via the anisotropically conductive film ACF, and then, the resin layer RSN which covers from a side surface of the optical element OD2 to the second area A2 is applied. The resin layer RSN is cured by, for example, ultraviolet irradiation.

Note that the manufacturing method of the display device 1 is not limited to the above-described method. For example, as will be described later, at least one of the first inorganic film IL1, the third organic film OL3, the second inorganic film IL2 and the fourth organic film OL4 may not be formed.

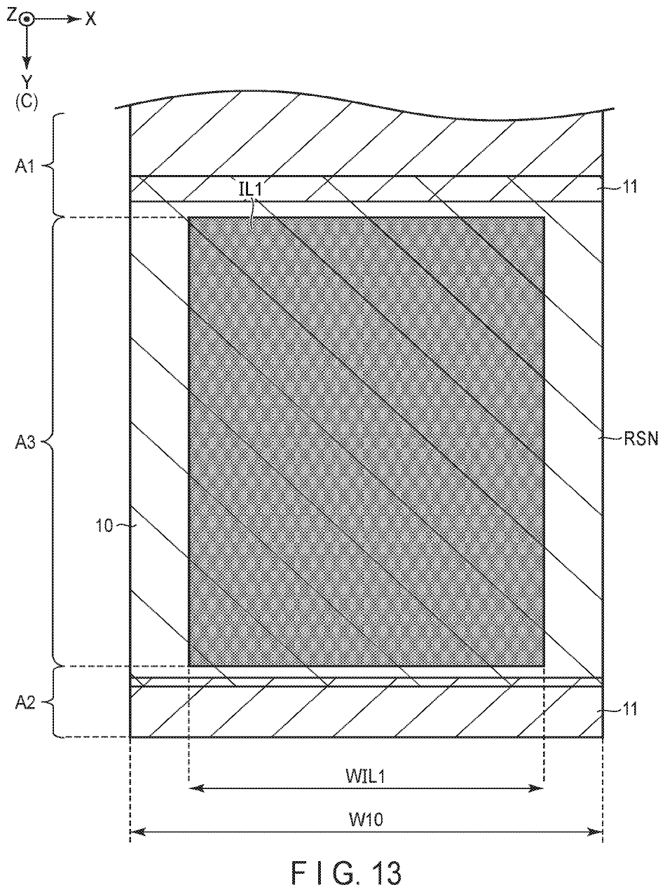

FIG. 13 is a plan view showing an example of the first inorganic film IL1 shown in FIG. 4. FIG. 13 shows the X-Y plane defined by the first direction X and the second direction Y for the sake of convenience, but the second direction Y corresponds to the circumferential direction C in a state where the third area A3 is bent. Note that, although the first inorganic film IL1 is illustrated as a typical example, the second inorganic film IL2 may have substantially the same shape.

The first inorganic film IL1 has, for example, a substantially rectangular shape. The first inorganic film IL1 is formed in the entire third area A3 in the second direction Y (or the circumferential direction C). On the other hand, the first inorganic film IL1 has a width WIL1 less than a width W10 of the insulating substrate 10 in the first direction X. In the illustrated example, the first inorganic film IL1 is located at substantially the center of the insulating substrate 10 in the first direction X.

Note that, as described with reference to FIG. 5, etc., the insulating film 11 is located in each of the first area A1 and the second area A2 as indicated by diagonal lines slanting upward to the right in the drawing. Although illustrations are omitted, the insulating films 12 and 13 are also located in each of the first area A1 and the second area A2 in the same manner. In addition, the resin layer RSN is located in the third area A3 and extends in a part of the first area A1 and a part of the second area A2 as indicated by diagonal lines slanting downward to the right in the drawing.

In planar view, the first inorganic film IL1 is separated from the insulating films 11 located respectively in the first area A1 and the second area A2. The resin layer RSN overlaps the first inorganic film IL1 in the third area A3 and overlaps the insulating films 11 respectively in the first area A1 and the second area A2.

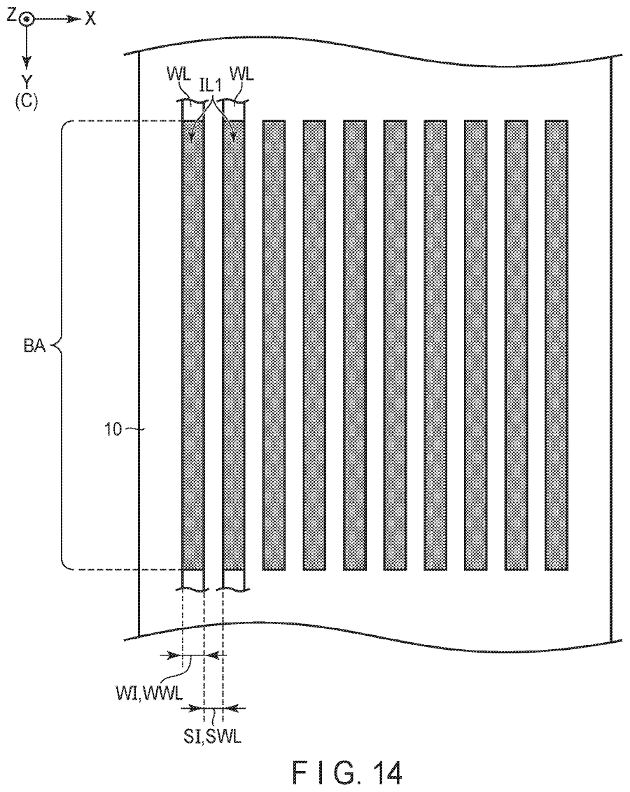

FIG. 14 is an illustration showing another example of the first inorganic film IL1. The example shown in FIG. 14 differs from the example shown in FIG. 13 in that the first inorganic film IL1 has the shape of a strip extending along the second direction Y. The first inorganic films IL1 have a substantially constant width WI and are arranged along the first direction X with a space SI in between. Here, the width WI and the space SI correspond to a length along the first direction X. The width WI is substantially equal to a width WWL of the wiring line WL located below the first inorganic film IL1. In addition, the space SI is substantially equal to a space SWL between the wiring lines WL. The first inorganic film IL1 substantially overlaps the wiring line WL in the illustrated example but may partly overlap or may not overlap the wiring line WL.

According to the present example, as compared to the example shown in FIG. 13, the rigidity of the first inorganic film IL1 is reduced, and generation of a crack in the first inorganic film IL1 can be suppressed.

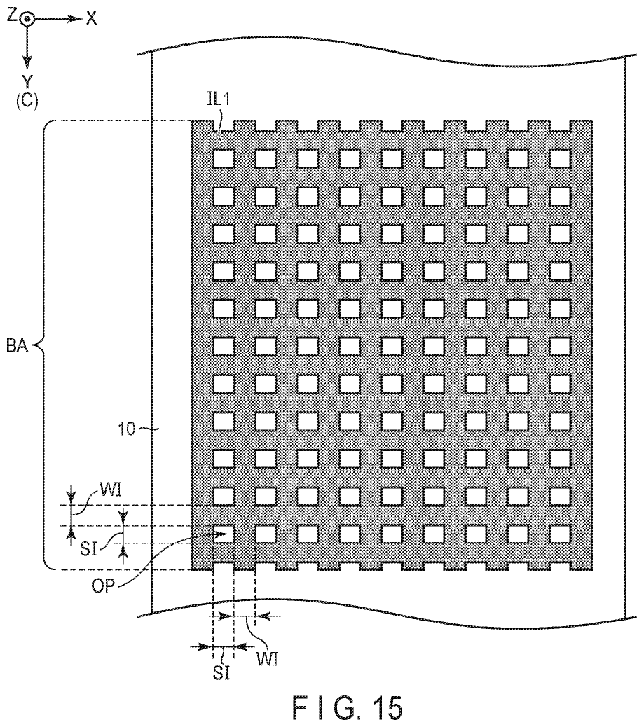

FIG. 15 is an illustration showing another example of the first inorganic film IL1. The example shown in FIG. 15 differs from the example shown in FIG. 13 in that the first inorganic film IL1 has the shape of a lattice. For example, the first inorganic film IL1 has openings OP having a substantially square shape. The openings OP are arranged in a matrix along the first direction X and the second direction Y. The lengths of four sides constituting the opening OP are equal to the above-described space SI. In addition, the space between the openings OP adjacent to each other in the first direction X and the space between the openings OP adjacent to each other in the second direction Y are equal to the above-described width WI.

The structure of the first inorganic film IL1 shown in FIG. 15 can be regard as the structure divided along the second direction Y of the first inorganic film IL shown in FIG. 14. That is, the structure including the opening OP forms a basic pattern, and the basic patterns are arranged along the second direction Y. In the example shown in FIG. 15, the effective length of the first inorganic film IL1, that is, the length along the second direction Y of the basic patterns is less than the length of the first inorganic film shown in FIG. 14. Therefore, when the third area A3 is bent, the effective radius of curvature of the first inorganic film IL1 is greater than that of the example shown in FIG. 14. Consequently, an increase in stress can be moderated, and generation of a crack in the first inorganic film IL1 can be suppressed.

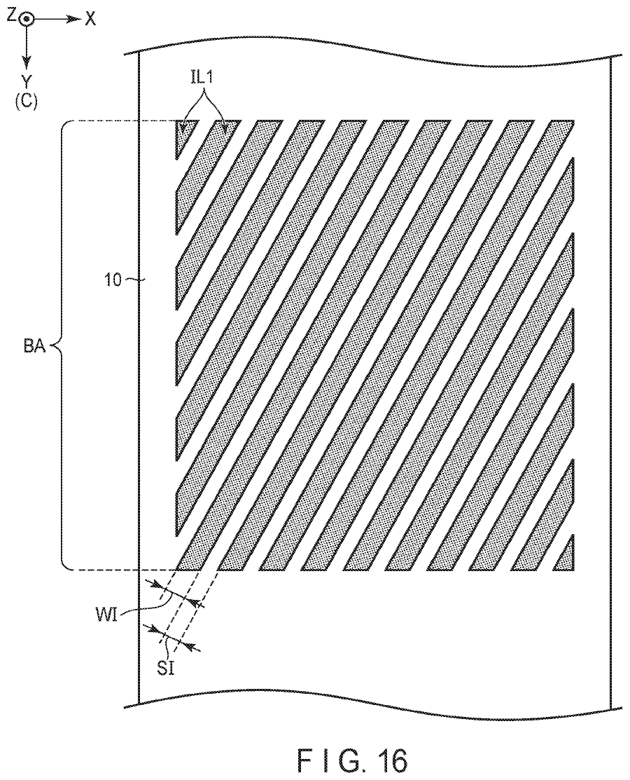

FIG. 16 is an illustration showing another example of the first inorganic film IL1. The example shown in FIG. 16 differs from the example shown in FIG. 14 in that the first inorganic film IL1 extends in a direction crossing the second direction Y. The first inorganic films IL1 have a substantially constant width WI and are arranged with the space SI in between. Here, the width WI and the space SI correspond to a length along a direction orthogonal to a direction in which the first inorganic film IL1 extends.

According to the present example, since the first inorganic film IL1 slants with respect to the second direction Y, when the third area A3 is bent, the effective radius of curvature of the first inorganic film IL1 increases. Consequently, an increase in stress can be moderated, and generation of a crack in the first inorganic film IL1 can be suppressed.

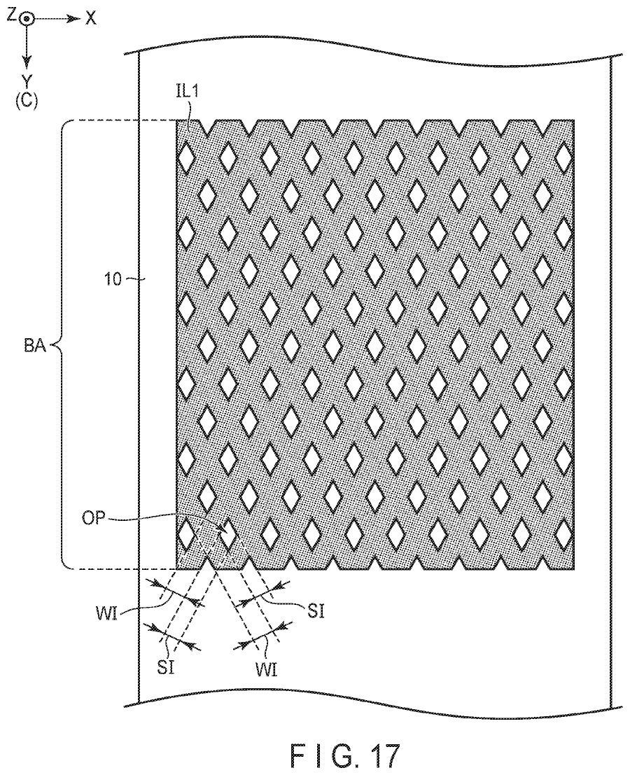

FIG. 17 is an illustration showing another example of the first inorganic film IL1. The example shown in FIG. 17 differs from the example shown in FIG. 13 in that the first inorganic film IL has the shape of a lattice. For example, the first inorganic film IL has openings OP having a substantially parallelogram shape. The openings OP are arranged at regular intervals along a direction in which the first inorganic film IL1 shown in FIG. 16 extends. The lengths of four sides constituting the opening OP are equal to the above-described space SI. In addition, the space between the openings OP adjacent to each other is equal to the above-described width WI.

The structure of the first inorganic film IL1 shown in FIG. 17 can be regarded as the structure divided along the second direction Y of the first inorganic film IL1 shown in FIG. 16. Therefore, in the present example also, the effective length of the first inorganic film IL1 is less than the length of the first inorganic film IL1 shown in FIG. 16. Therefore, when the third area A3 is bent, the effective radius of curvature of the first inorganic film IL1 is greater than that of the example shown in FIG. 16. Consequently, an increase in stress can be moderated, and generation of a crack in the first inorganic film IL1 can be suppressed.

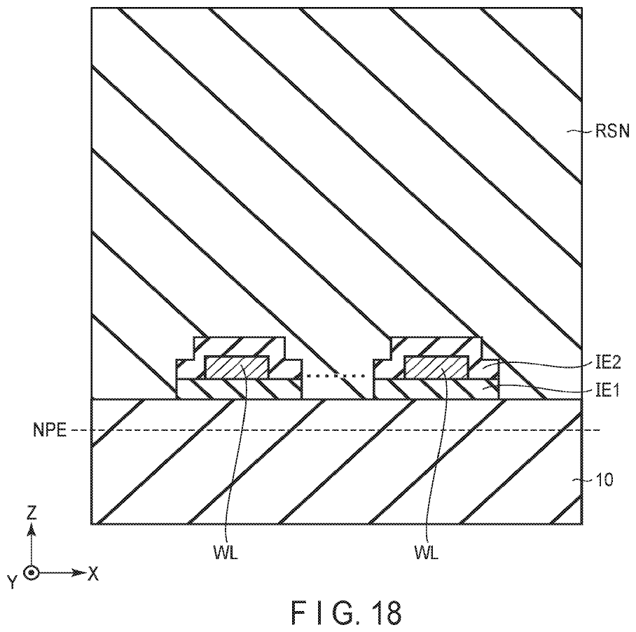

FIG. 18 is a cross-sectional view showing the configuration of the third area A3 as a comparative example. The example shown in FIG. 18 differs from the example shown in FIG. 4 in that the wiring line WL is covered with an inorganic insulating film.

Furthermore, in FIG. 18, each wiring line WL is covered with an inorganic film. That is, the resin layer RSN is in contact with the insulating substrate 10 between the wiring lines WL adjacent to each other.

In this configuration, when the third area A3 is bent, as indicated by a dashed line, a neutral plane NPE is located more downward than the neutral plane NP shown in FIG. 4. In other words, the neutral plane NPE in the comparative example is located farther from the wiring line WL than the neutral plane NP shown in FIG. 4. Therefore, in the comparative example, a tensile stress higher than that of the example shown in FIG. 4 is applied to the vicinity of the wiring line WL.

In general, an inorganic film is more fragile than an organic film, and a crack is more likely to be caused by a stress. When the wiring line WL is directly formed on an inorganic film, such a crack propagates to the wiring line WL and causes the wiring line WL to break. In addition, if a crack is generated in an inorganic film covering the wiring line WL, moisture intrudes and corrodes the wiring line WL.

On the other hand, according to the present embodiment, the wiring line WL is sandwiched between the first organic film OL1 and the second organic film OL2 which are made of an organic insulating material at least in the third area A3. Therefore, as compared to the comparative example shown in FIG. 18, generation of a crack in the organic film covering the wiring line WL can be suppressed. In addition, since the wiring line WL is not directly in contact with the first inorganic film IL1 and the second inorganic film IL2, even if a crack is generated in the inorganic film, the organic film between the wiring line WL and the inorganic film absorbs the impact of the crack, and propagation of the crack can be suppressed. As a result, the display device which can suppress breaking of the wiring line WL and improve reliability is provided.

In addition, the first organic film OL1 and the second organic film OL2 which are in contact with the wiring line WL are formed of polyimide containing fluorine. When polyimide contains fluorine, moisture permeability and moisture absorbency are reduced, and corrosion of the wiring line WL can be suppressed.

Furthermore, according to the present embodiment, the first inorganic film IL1 and the second inorganic film IL2 having higher Young's moduli than those of the first organic film OL1 and the second organic film OL2 are disposed more upward (or closer to the outer circumference when bent) than the wiring line WL. Accordingly, even if the resin layer RSN is plastically deformed, a change of the position of the neutral plane NP in a direction away from the wiring line WL can be suppressed. More specifically, when the third area A3 is bent, the resin layer RSN located at the outermost circumference is highly deformed (extended) and is therefore often plastically deformed. When the resin layer RSN is plastically deformed, the Young's modulus is significantly reduced. At this time, the resin layer RSN makes hardly any contribution to the neutral plane PSN. However, according to the present embodiment, since the first inorganic film IL1 and the second inorganic film IL2 are disposed more upward than the wiring line WL, the position of the neutral plane NP can be brought close to the wiring line WL. Therefore, an increase in stress in the vicinity of the wiring line WL can be suppressed, and breaking of the wiring line WL can be suppressed.

In addition, as shown in FIGS. 14 to 17, the first inorganic film IL1 and the second organic film IL2 are formed in the shape of a strip or a lattice with a substantially equal pitch to the pitch of the wiring line WL. Therefore, generation of a crack in the first inorganic film IL1 and the second inorganic film IL2 can be suppressed. As a result, when the third area A3 is bent, the position of the neutral plane can be maintained. Therefore, an increase in stress in the vicinity of the wiring line WL can be suppressed, and breaking of the wiring line WL can be suppressed.

Furthermore, the second organic film OL2, the first inorganic film IL1, the third organic film OL3, the second inorganic film IL2 and the fourth organic film OL4 can be formed simultaneously with the insulating film 14, the insulating film 15, the insulating film 16, the sealing film 17 and the resist film 18 in the first area A1. Therefore, it is possible to easily form them without increasing the number of manufacturing processes.

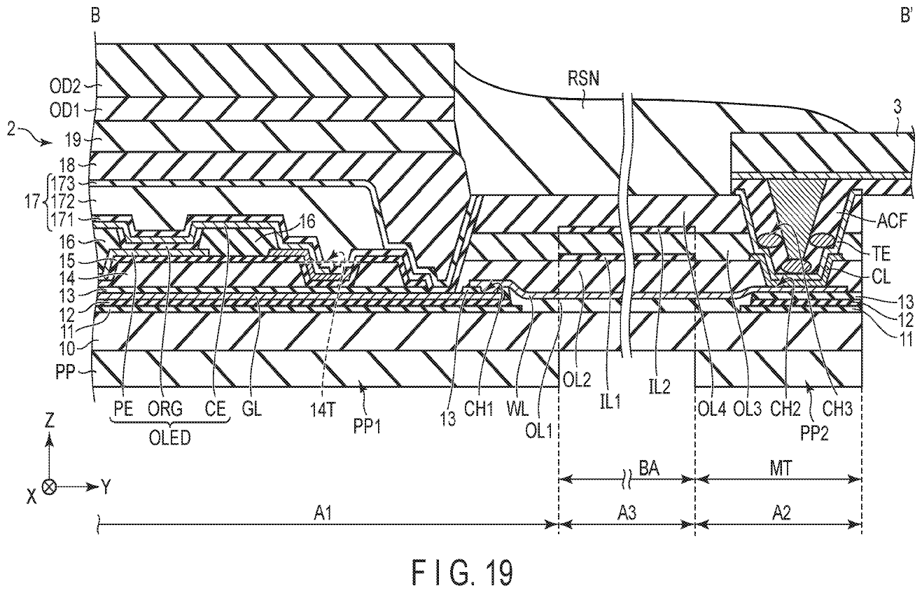

Next, a modification example of the present embodiment will be described with reference to FIG. 19.

FIG. 19 is a cross-sectional view taken along line B-B′ shown in FIG. 1. The illustrated modification example differs from the configuration example shown in FIG. 5 in that the fourth organic film OL4 is formed on the entire surface of the third organic film OL3.

In the configuration example shown in FIG. 5, the second inorganic film IL2 is formed of the inorganic film 171 and the inorganic film 173 which constitute the sealing film 17. On the other hand, in the present modification example, the second inorganic film IL2 is formed of another inorganic film.

In this case, the second inorganic film IL2 is formed by, for example, plasma CVD in a separate process from the process of forming the sealing film 17. After that, the fourth organic film OL4 is formed to cover the second inorganic film IL2 and be in contact with the third organic film OL3. In the second area A2, the contact hole CH3 penetrating the fourth organic film OL4 and the third organic film OL3 to expose the conductive layer CL is formed. The terminal TE is disposed in this contact hole CH3 and is in contact with the conductive layer CL. Accordingly, the terminal TE and the wiring line WL are electrically connected to each other via the conductive layer CL. In the illustrated example, the films up to the fourth organic film OL4 are formed in the third area A3, and then, the sealing film 17 and the resist film 18 are formed. However, they are not necessarily formed in this manner.

In the same manner as the above-described embodiment, the second inorganic film IL2 is not formed at the third area A3 side end of the first area A1 which is particularly likely to be subjected to a stress when the display panel 2 is bent. The adhesion between the third organic film OL3 and the second inorganic film IL2 and the adhesion between the fourth organic film OL4 and the second inorganic film IL2 are lower than the adhesion between the third organic film OL3 and the fourth organic film OL4, and when the display panel 2 is bent, the second inorganic film IL2 is likely to peel off. If the second inorganic film IL2 is formed of the inorganic film 171, etc., which constitutes the sealing film 17 continuously from the first area A1 to the third area A3, peeling of the second inorganic film IL2 in the third area A3 causes the inorganic film 171, etc., to peel off and further causes members in the display area DA to peel off.

In the present modification example also, the second inorganic film IL2 is smaller than the third organic film OL3 and the fourth organic film OL4. Therefore, the first area A1 includes a portion in which the third organic film OL3 and the fourth organic film OL4 are in contact with each other on its third area A3 side, and when the display panel 2 is bent and even if the second inorganic film IL2 peels off, the third organic film OL3 and the fourth organic film OL4 are firmly bonded to each other, and propagation of the impact of the peeling can be suppressed.

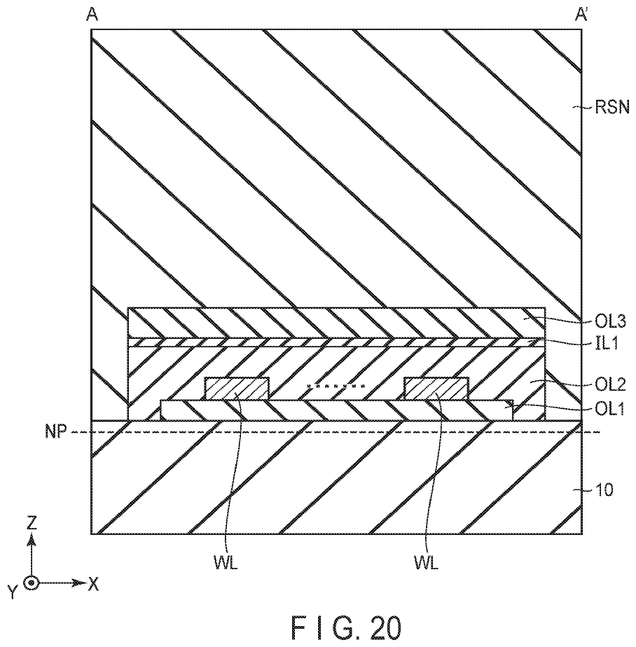

Other examples of the third area A3 will be described with reference to FIGS. 20 to 24.

FIG. 20 is a cross-sectional view showing another example of the third area A3. The example shown in FIG. 20 differs from the example shown in FIG. 4 in that the second inorganic film IL2 and the fourth organic film OL4 are not disposed on the third organic film OL3. Since the first inorganic film IL1 having a higher Young's modulus than those of the first to third organic films OL1 to OL3 is located more upward than the wiring line WL1, the neutral plane NP is located closer to the wiring line WL than that of the comparative example shown in FIG. 18.

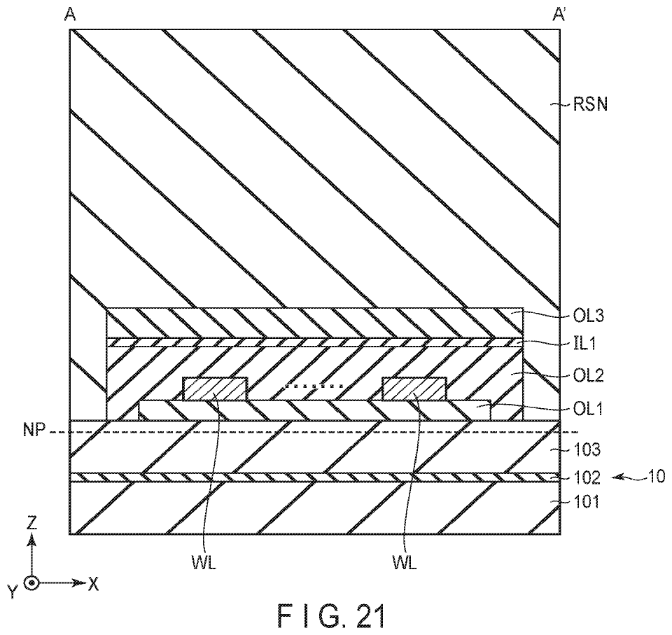

FIG. 21 is a cross-sectional view showing another example of the third area A3. The example shown in FIG. 21 differs from the example shown in FIG. 20 in that an inorganic film 102 is disposed in the insulating substrate 10. That is, the insulating substrate 10 has a laminated structure having organic films 101 and 103 and an inorganic film 102 located between the organic film 101 and the organic film 103. The organic films 101 and 103 are formed of, for example, an organic insulating material such as polyimide. The organic film 102 is formed of, for example, an inorganic insulating material such as silicon oxide or silicon nitride.

Since the inorganic film 102 having a high Young's modulus is located more downward than the wiring line WL, the neutral plane NP in the present example is located slightly farther from the wiring line WL than the neutral plane in FIG. 20. However, in the present example also, the neutral plane NP is located closer to the wiring line WL than that of the comparative example shown in FIG. 18.

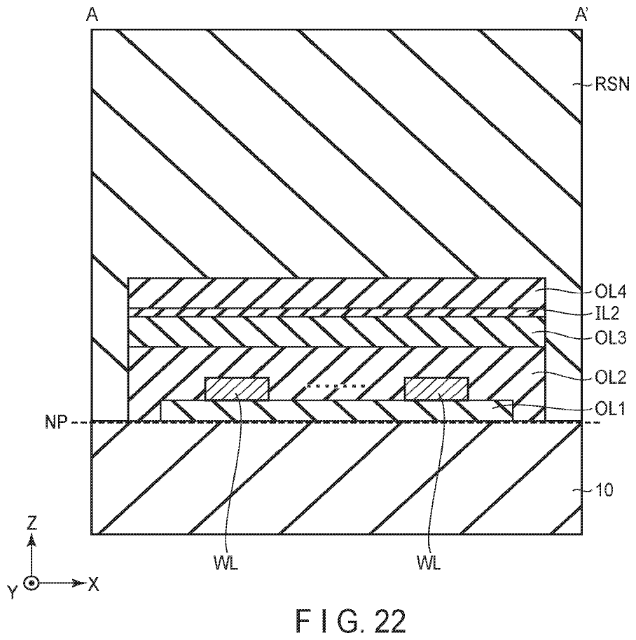

FIG. 22 is a cross-sectional view showing another example of the third area A3. The example shown in FIG. 22 differs from the example shown in FIG. 20 in that the first inorganic film IL1 is not disposed between the second organic film OL2 and the third organic film OL3 and the second inorganic film IL2 and the fourth organic film OL4 are disposed on the third organic film OL3. The second inorganic film IL2 is arranged more upward, in other words, closer to the outer circumference when bent than the first inorganic film IL1 shown in FIG. 20. According to the configuration of the present example, the neutral plane NP can be located closer to the wiring line WL than that of the example shown in FIG. 20.

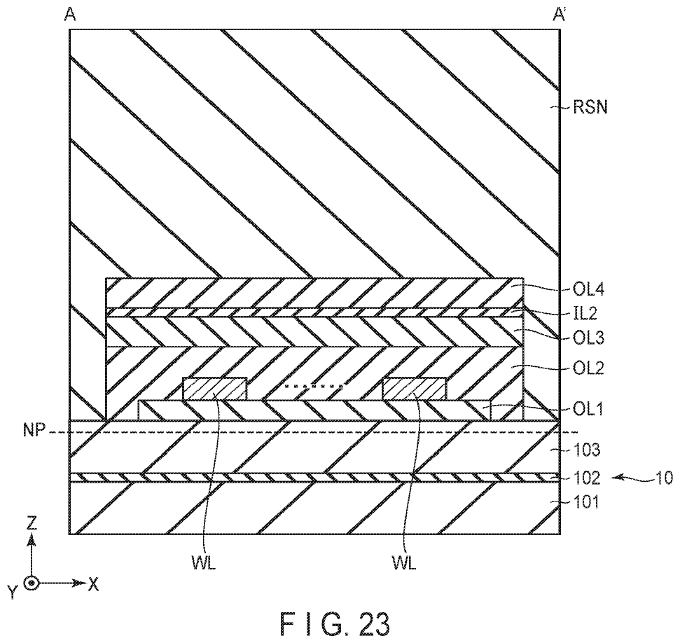

FIG. 23 is a cross-sectional view showing another example of the third area A3. The example shown in FIG. 23 differs from the example shown in FIG. 22 in that the inorganic film 102 is disposed in the insulating substrate 10. Since the inorganic film 102 having a high Young's modulus is located more downward than the wiring line WL, the neutral plane NP in the present example is located slightly farther from the wiring line WL than the neutral plane in FIG. 22. However, in the present example also, the neutral plane NP is located closer to the wiring line WL than that of the comparative example shown in FIG. 18.

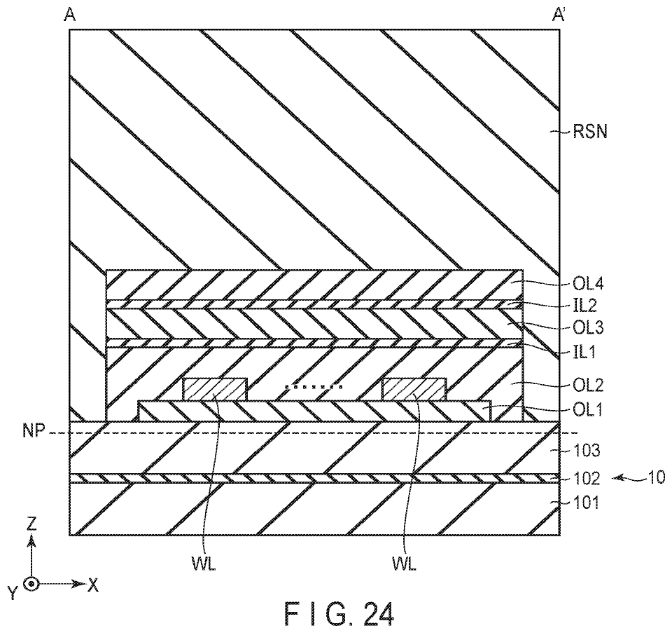

FIG. 24 is a cross-sectional view showing another example of the third area A3. The example shown in FIG. 24 differs from the example shown in FIG. 4 in that the inorganic film 102 is disposed in the insulating substrate 10. Since the inorganic film 102 having a high Young's modulus is located more downward than the wiring line WL, the neutral plane NP in the present example is located slightly farther from the wiring line WL than the neutral plane in FIG. 4. However, in the present example also, the neutral plane NP is located closer to the wiring line WL than that of the comparative example shown in FIG. 18.

As described above, in the examples shown in FIGS. 20 to 24 also, the neutral plane NP is located closer to the wiring line WL than the neutral plane NPE in the comparative example. Therefore, an increase in stress in the vicinity of the wiring line WL can be suppressed. As a result, the display device which can suppress breaking of the wiring line WL and improve reliability is provided.

In addition, according to the examples shown in FIGS. 22 and 23, the inorganic film having a higher Young's modulus than those of the organic films is disposed only at a position even farther from the wiring line WL (even closer to the outer circumference when bent) above the wiring line WL. Accordingly, even if the resin layer RSN is plastically deformed, as compared to the examples shown in FIGS. 20 and 21, the change of the position of the neutral plane NP in the direction away from the wiring line WL can be further suppressed. More specifically, when the third area A3 is bent, the resin layer RSN located at the outermost circumference is highly deformed (extended) and is therefore often plastically deformed. When the resin layer RSN is plastically deformed, the Young's modulus is significantly reduced. At this time, the resin layer RSN makes hardly any contribution to the neutral plane. However, according to the present embodiment, since the second inorganic film IL2 is disposed at a farther position above the wiring line WL, as compared to a case where only the first inorganic film IL1 is disposed at a closer position above the wiring line WL, the position of the neutral plane NP can be brought even closer to the wiring line WL. Therefore, an increase in stress in the vicinity of the wiring line WL can be suppressed, and breaking of the wiring line WL can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a substrate having a first area including a display area, a second area including a mounting area, and a third area located between the first area and the second area;
a first organic film disposed on the substrate in the third area;
a plurality of wiring lines arranged at intervals in a first direction on the first organic film, and extending in a second direction crossing the first direction;
a second organic film covering the first organic film and the wiring lines in the third area; and
a first inorganic film disposed on the second organic film.

2. The display device of claim 1, wherein a part of the second organic film overlaps the first area and the second area.

3. The display device of claim 1, wherein the first inorganic film does not overlap inorganic films formed in the first area and the second area.

4. The display device of claim 1, further comprising a third organic film covering the first inorganic film, wherein
the third organic film is in contact with the second organic film at a position closer to the first area than the first inorganic film and at a position closer to the second area than the first inorganic film.

5. The display device of claim 4, wherein a part of the third organic film is in contact with a part of the second organic film in the first direction.

6. The display device of claim 1, wherein the first inorganic film is formed in a shape of a strip extending in the second direction.

7. The display device of claim 1, wherein the first inorganic film is formed in a shape of a lattice.

8. The display device of claim 4, further comprising:
a second inorganic film disposed at a position overlapping the first inorganic film on the third organic film; and
a fourth organic film disposed on the second inorganic film.

9. The display device of claim 8, wherein the fourth organic film is in contact with the third organic film at a position closer to the first area than the second inorganic film and at a position closer to the second area than the second inorganic film.

10. The display device of claim 8, wherein a part of the fourth organic film is in contact with a part of the third organic film in the first direction.

11. The display device of claim 1, further comprising:
an optical member disposed on the first area;
a wiring substrate connected to the mounting area; and
a resin layer disposed from an end of the optical member to an end of the wiring substrate.

12. The display device of claim 8, further comprising:
an optical member disposed on the first area;
a wiring substrate connected to the mounting area; and
a resin layer disposed from an end of the optical member to an end of the wiring substrate, wherein
the resin layer covers the fourth organic film and is in contact with a part of the third organic film.

13. The display device of claim 11, wherein a Young's modulus of the first organic film and a Young's modulus of the second organic film are greater than a Young's modulus of the resin layer.

14. The display device of claim 1, wherein the first organic film and the second organic film contain fluorine.

15. The display device of claim 1, wherein the substrate is bent in the third area such that the first area and the second area are opposed to each other.

16. A display device comprising:
a substrate having a first area including a display area, a second area including a mounting area, and a third area located between the first area and the second area, and bent in the third area such that the first area and the second area are opposed to each other;
a first organic film formed on the substrate in the third area;
wiring lines arranged at intervals in a first direction on the first organic film;
a second organic film covering the wiring lines and the first organic film; and
a first inorganic film formed on the second organic film.

17. The display device of claim 16, further comprising a third organic film formed between the second organic film and the first inorganic film in the third area.

18. The display device of claim 17, further comprising a second inorganic film formed between the second organic film and the third organic film in the third area, wherein
the second inorganic film is disposed at a position overlapping the first inorganic film.

19. The display device of claim 16, further comprising a fourth organic film located on the first inorganic film in the third area.
